(19) United States
(12) Patent Application Publication
(10) Pub. No.: US 2026/0075933 A1
(43) Pub. Date: Mar. 12, 2026

(54) SEMICONDUCTOR DEVICE INCLUDING VERTICALLY ARRANGED TRANSISTORS

(71) Applicant: SAMSUNG ELECTRONICS CO., LTD., Suwon-si (KR)

(72) Inventors: Minsoo Lee, Suwon-si (KR); Byounghoon Lee, Suwon-si (KR); Jinyong Shim, Suwon-si (KR); Naeun Jung, Suwon-si (KR); Musarrat Hasan, Suwon-si (KR); Joonnyung Heo, Suwon-si (KR)

(73) Assignee: SAMSUNG ELECTRONICS CO., LTD., Suwon-si (KR)

(21) Appl. No.: 19/080,156

(22) Filed: Mar. 14, 2025

(30) Foreign Application Priority Data
Sep. 6, 2024 (KR) 10-2024-0121500

(51) Int. Cl. H10D 84/83; H10D 84/85

(52) U.S. Cl. CPC H10D 84/8314; H10D 84/851

(57) ABSTRACT

A semiconductor device includes a first substrate, a first active pattern including a first lower pattern and a plurality of first sheet patterns, a first gate structure surrounding the plurality of first sheet patterns, a first high-k insulating film disposed between the first gate structure and the plurality of first sheet patterns, a first gate insulating film disposed between the plurality of first sheet patterns and the first high-k insulating film, a plurality of second sheet patterns, a second gate structure surrounding the plurality of second sheet patterns, and a second high-k insulating film disposed between the second gate structure and the plurality of second sheet patterns, wherein the first high-k insulating film includes a first dopant, the second high-k insulating film includes a second dopant different from the first dopant, and the second dopant includes at least one of silicon, aluminum, zirconium, yttrium, scandium, nitrogen, gadolinium, and germanium.

### CROSS-REFERENCE TO RELATED APPLICATION

This application is based on and claims priority to Korean Patent Application No. 10-2024-0121500, filed in the Korean Intellectual Property Office on Sep. 6, 2024, the entire contents of which are hereby incorporated by reference.

### BACKGROUND

### 1. Field The present disclosure relates to a semiconductor device.

### 2. Description of Related Art

Semiconductor devices of electronic devices are key components for controlling or amplifying electrical signals, and various types of semiconductor devices can be manufactured. For example, memory devices can be used primarily to store and retrieve data, while non-memory devices can be used to control or amplify electrical signals. Such semiconductor devices are key components of electronic devices and play an important role in a variety of fields including computers, communications equipment, and consumer electronics.

As industry develops, expectations for the performance and functionality of electronic devices continues to grow. Accordingly, high-performance properties of semiconductor devices are essential, and the degree of integration of the semiconductor devices has been enhanced to meet such demands. Research has been conducted on various methods of forming semiconductor devices with superior performance and improved integration.

### SUMMARY

Provided is a semiconductor device with improved integration and reliability.

According to one or more embodiments of the present disclosure, it may be possible to enhance the reliability of a semiconductor device by forming a second high-k insulating film at a relatively low temperature.

According to one or more embodiments of the present disclosure, a second sheet pattern may be thinner than a first sheet pattern, so that the degree of integration of a semiconductor device may be improved.

According to an aspect of the disclosure, a semiconductor device includes: a first substrate; a first active pattern extending in a first direction on the first substrate, the first active pattern including a first lower pattern and a plurality of first sheet patterns spaced apart from each other on the first lower pattern; a first gate structure extending in a second direction intersecting with the first direction, wherein the first gate structure surrounds the plurality of first sheet patterns; a first high-k insulating film between the first gate structure and the plurality of first sheet patterns; a first gate insulating film between the plurality of first sheet patterns and the first high-k insulating film; a plurality of second sheet patterns above the plurality of first sheet patterns, wherein the plurality of second sheet patterns are spaced apart from each other; a second gate structure extending in the second direction, wherein the second gate structure surrounds the plurality of second sheet patterns; and a second high-k insulating film between the second gate structure and the plurality of second sheet patterns, wherein the first high-k insulating film includes a first dopant, wherein the second high-k insulating film includes a second dopant different from the first dopant, and wherein the second dopant includes at least one of silicon, aluminum, zirconium, yttrium, scandium, nitrogen, gadolinium, or germanium.

According to an aspect of the disclosure, a semiconductor device includes: a first substrate; a first active pattern extending in a first direction on the first substrate, the first active pattern including a plurality of first sheet patterns spaced apart from each other; a first gate structure extending in a second direction intersecting with the first direction, wherein the first gate structure surrounds the plurality of first sheet patterns; a first high-k insulating film between the first gate structure and the plurality of first sheet patterns, the first high-k insulating film including a first dopant; a first gate insulating film between the plurality of first sheet patterns and the first high-k insulating film; a second active pattern extending in the first direction and spaced apart from the first active pattern in a third direction, wherein the third direction intersects with the first and the second directions, and wherein the second active pattern includes a plurality of second sheet patterns spaced apart from each other in the third direction; a second gate structure extending in the second direction, wherein the second gate structure surrounds the plurality of second sheet patterns; and a second high-k insulating film between the second gate structure and the plurality of second sheet patterns, the second high-k insulating film including a second dopant different from the first dopant, wherein a concentration of the first dopant decreases as a distance from an interface between the first gate insulating film and the first high-k insulating film increases in the third direction, and wherein a concentration of the second dopant is constant in the third direction.

According to an aspect of the disclosure, a semiconductor device includes: a first substrate; a first active pattern extending in a first direction on the first substrate, the first active pattern including a first lower pattern and a plurality of first sheet patterns spaced apart from each other on the first lower pattern; a first gate structure extending in a second direction intersecting with the first direction, wherein the first gate structure surrounds the plurality of first sheet patterns; a first high-k insulating film between the first gate structure and the plurality of first sheet patterns; a first gate insulating film between the plurality of first sheet patterns and the first high-k insulating film; a gate capping pattern on an upper surface of the first gate structure; a bonding layer on the gate capping pattern; a second substrate on the bonding layer; a second active pattern extending in the first direction on the second substrate, the second active pattern including a second lower pattern and a plurality of second sheet patterns spaced apart from each other on the second lower pattern; a second gate structure extending in the second direction, wherein the second gate structure surrounds the plurality of second sheet patterns; a second high-k insulating film between the second gate structure and the plurality of second sheet patterns; and a second gate insulating film between the plurality of second sheet patterns and the second high-k insulating film, wherein the first high-k insulating film includes a first high-k material and a first dopant, wherein the second high-k insulating film includes a second high-k material different from the first high-k material and a second dopant different from the first dopant, wherein a concentration of the first dopant decreases as a distance from an interface between the first gate insulating film and the first high-k insulating film increases in a third direction, wherein the third direction is perpendicular to an upper surface of the first substrate, and wherein a concentration of the second dopant is constant in the third direction.

### BRIEF DESCRIPTION OF THE DRAWINGS

The above and other aspects and features of the present disclosure will become more apparent from the following description taken in conjunction with the accompanying drawings, in which:

FIG. 1 shows a layout of a semiconductor device according to one or more embodiments of the present disclosure;

FIG. 2 is a cross-sectional view taken along line A-A in FIG. 1;

FIG. 3 is a cross-sectional view taken along line B-B in FIG. 1;

FIG. 4 is an enlarged view illustrating the Q1 region in FIG. 3;

FIG. 5 is a graph schematically illustrating the concentration of a first dopant along LINE1 in FIG. 4;

FIG. 6 is an enlarged view illustrating the Q2 region in FIG. 3;

FIG. 7 is a graph schematically illustrating the concentration of a second dopant along LINE2 in FIG. 6;

FIGS. 8 and 9 are views illustrating a semiconductor device according to one or more embodiments of the present disclosure;

FIGS. 10 and 11 are views illustrating a semiconductor device according to one or more embodiments of the present disclosure; and

FIGS. 12 through 21 illustrate intermediate operations of a method of manufacturing a semiconductor device according to one or more embodiments of the present disclosure.

### DETAILED DESCRIPTION

A semiconductor device according to one or more embodiments of the present disclosure may include a metal-oxide-semiconductor field-effect transistor (MOSFET), and, more specifically, may include a three-dimensional multi-stack semiconductor device referred to as a gate-all-around (GAA) transistor or a multi-bridge channel FET (MBCFET).

Hereinafter, with reference to the drawings, a semiconductor device and a method of manufacturing the same according to one or more embodiments of the present disclosure will be described in detail. In the following description, like reference numerals refer to like elements throughout the specification.

As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element, wherein the indirect connection includes “connection via a wireless communication network”.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c. ”

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

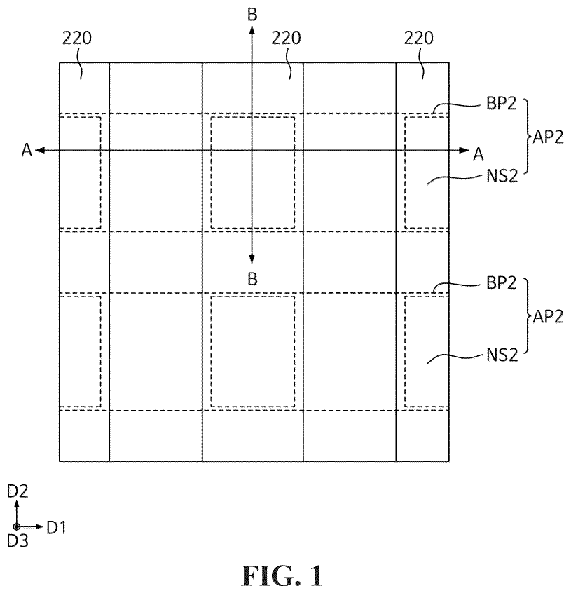

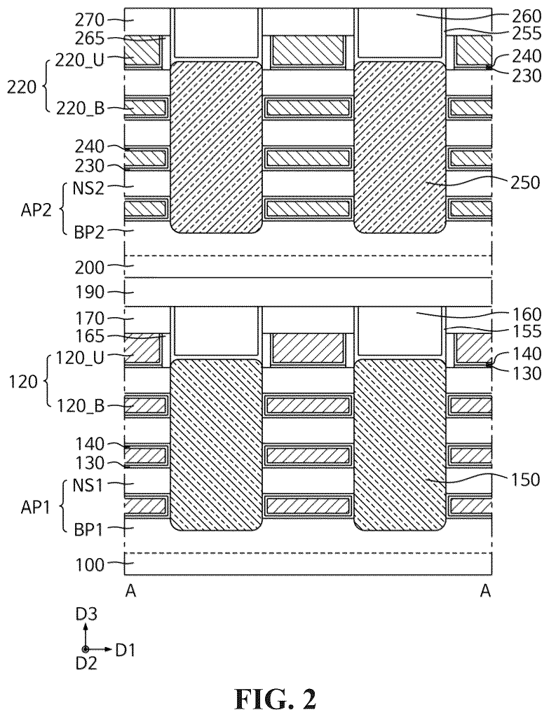

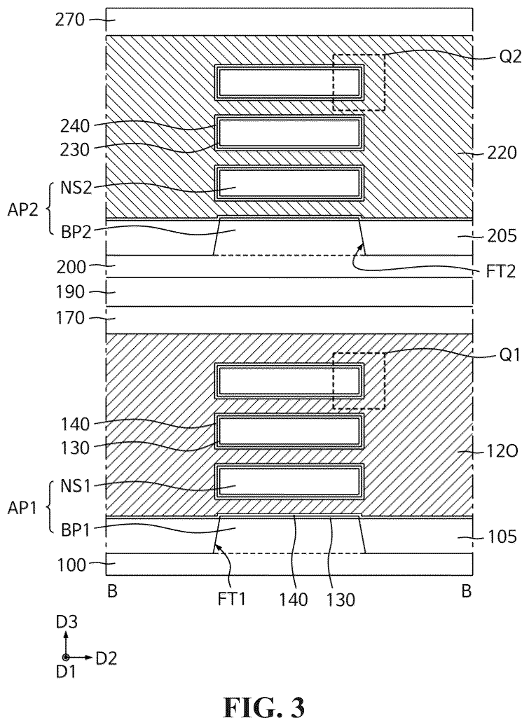

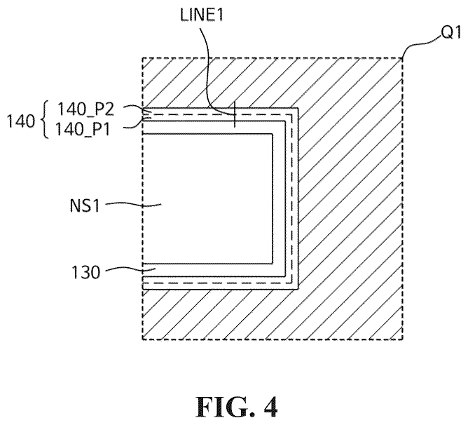

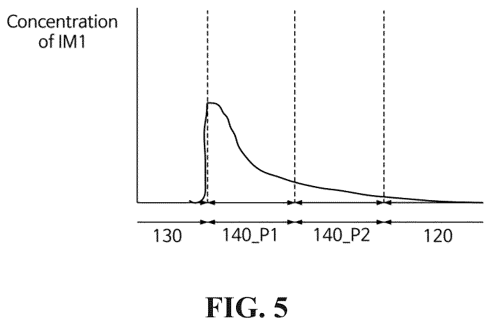

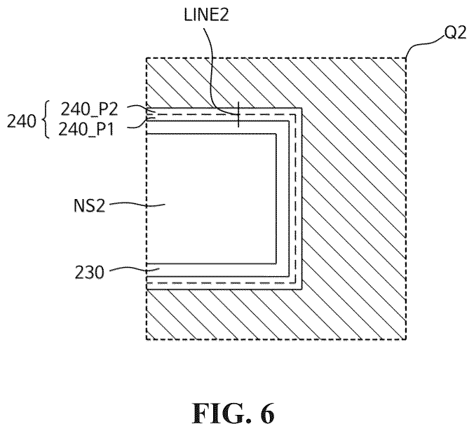

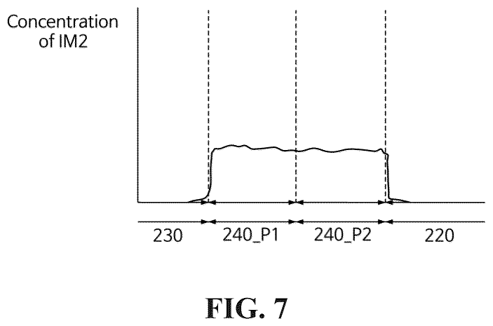

FIG. 1 shows a layout for illustrating a semiconductor device according to one or more embodiments of the present disclosure. FIG. 2 is a cross-sectional view taken along line A-A in FIG. 1. FIG. 3 is a cross-sectional view taken along line B-B in FIG. 1. FIG. 4 is an enlarged view for illustrating the Q1 region in FIG. 3. FIG. 5 is a graph for schematically illustrating the concentration of a first dopant along LINE1 in FIG. 4. FIG. 6 is an enlarged view for illustrating the Q2 region in FIG. 3. FIG. 7 is a graph for schematically illustrating the concentration of a second dopant along LINE2 in FIG. 6.

Referring to FIGS. 1 through 7, the semiconductor device according to one or more embodiments may include a first substrate 100, a first active pattern AP1, a first gate structure 120, a first gate insulating film 130, a first high-k insulating film 140, a first source/drain pattern 150, a first gate capping pattern 170, a bonding layer 190, a second substrate 200, a second active pattern AP2, a second gate structure 220, a second gate insulating film 230, a second high-k insulating film 240, a second source/drain pattern 250, etc.

The first substrate 100 may be bulk silicon or silicon-on-insulator (SOI). In one or more embodiments, the first substrate 100 may contain silicon germanium (SiGe), silicon germanium on insulator (SGOI), indium antimonide, lead telluride, indium arsenide, indium phosphide, gallium arsenide, or gallium antimonide, but the present disclosure is not limited thereto.

The first active pattern AP1 may be disposed on the first substrate 100. The first active pattern AP1 may extend in a first direction D1. The first active pattern AP1 may be spaced apart from the first active pattern AP1 adjacent thereto in a second direction D2. Here, the first direction D1 may intersect with the second direction D2, and may be perpendicular to the second direction D2, for example. Each of the first direction D1 and the second direction D2 may be parallel to an upper surface of the first substrate 100.

The first active pattern AP1 may be a multi-channel active pattern. The first active pattern AP1 may include a first lower pattern BP1 and a plurality of first sheet patterns NS1.

The first lower pattern BP1 may protrude from the first substrate 100. The first lower pattern BP1 may extend in the first direction D1. The first lower pattern BP1 may be spaced apart from the first lower pattern BP1 adjacent thereto in the second direction D2. The first lower pattern BP1 and the first lower pattern BP1 adjacent thereto may be separated by a first field trench FT1. The first field trench FT1 may be defined as the upper surface of the first substrate 100 and a side surface of the first lower pattern BP1.

The plurality of first sheet patterns NS1 may be disposed on the first lower pattern BP1. The plurality of first sheet patterns NS1 may be spaced apart from the first lower pattern BP1 in a third direction D3. The first sheet patterns NS1 may be spaced apart from each other in the third direction D3. Here, the third direction D3 may intersect with each of the first direction D1 and the second direction D2. The third direction D3 may be perpendicular to the upper surface of the first substrate 100. The third direction D3 may be a thickness direction of the first substrate 100. In one or more embodiments of the present disclosure, the first sheet pattern NS1 may have a nanosheet shape. Three first sheet patterns NS1 have been illustrated, but the present disclosure is not limited thereto.

The first lower pattern BP1 may be formed by etching a portion of the first substrate 100, but the present disclosure is not limited thereto. For example, the first lower pattern BP1 may include an epitaxial layer grown from the first substrate 100. The first lower pattern BP1 may contain an elemental semiconductor material, such as silicon (Si) or germanium (Ge). In addition, the first lower pattern BP1 may contain a compound semiconductor. For example, the first lower pattern BP1 may contain a group IV-IV compound semiconductor or a group III-V compound semiconductor.

For example, the group IV-IV compound semiconductor may be a binary compound or ternary compound containing at least two of carbon (C), silicon (Si), germanium (Ge), and tin (Sn).

For example, the group III-V compound semiconductor may be a binary compound, a ternary compound, or a quaternary compound formed by combining at least one of aluminum (Al), gallium (Ga), and indium (In), which are group III elements, with one of phosphorus (P), arsenic (As), and antimony (Sb), which are group V elements.

The first sheet pattern NS1 may contain one of an elemental semiconductor material, such as silicon (Si) or silicon germanium (SiGe), the group IV-IV compound semiconductor, and the group III-V compound semiconductor. The plurality of first sheet patterns NS1 may contain the same material as the first lower pattern BP1 or a material different from that in the first lower pattern BP1.

In one or more embodiments, the first lower pattern BP1 and the plurality of first sheet patterns NS1 may contain silicon (Si). In another embodiment, the first lower pattern BP1 and the plurality of first sheet patterns NS1 may contain silicon germanium (SiGe). In still another embodiment, the first lower pattern BP1 may contain silicon (Si), and the plurality of first sheet patterns NS1 may contain silicon germanium (SiGe).

A first field insulating film 105 may be disposed on the first substrate 100. The first field insulating film 105 may fill a portion of the first field trench FT1. The first field insulating film 105 may be disposed between the first lower patterns BP1 adjacent to each other. The first field insulating film 105 may extend in the first direction D1. The first field insulating film 105 may be formed on the upper surface of the first substrate 100. The first field insulating film 105 may cover a portion of a sidewall of the first lower pattern BP1. For example, as illustrated in FIG. 3, the first field insulating film 105 may cover the sidewall of the first lower pattern BP1, but may not be disposed on the upper surface of the first lower pattern BP1. In other words, the first field insulating film 105 may not be disposed between the upper surface of the first lower pattern BP1 and the first sheet pattern NS1.

The first field insulating film 105 may contain, for example, an oxide, a nitride, a nitroxide, or combinations thereof. The first field insulating film 105 formed of a single film has been illustrated, which is only for convenience of description, but the present disclosure is not limited thereto. For example, the first field insulating film 105 may be formed of multiple films.

The first gate structure 120 may extend in the second direction D2 on the first substrate 100. The first gate structure 120 may intersect with the first active pattern AP1. The first gate structure 120 may be disposed on the first lower pattern BP1. The first gate structure 120 may be spaced apart from the first gate structure 120 adjacent thereto in the first direction D1. The first gate structure 120 may surround the plurality of first sheet patterns NS1. The first gate structure 120 may surround four sides of the first sheet pattern NS1. For example, the first gate structure 120 may surround an upper surface, a lower surface, and both side surfaces of the first sheet pattern NS1. Here, the upper and lower surfaces of the first sheet pattern NS1 may face each other in the third direction D3, and the two side surfaces of the first sheet pattern NS1 may face each other in the second direction D2.

The first gate structure 120 may include a first upper gate electrode 120_U and a first lower gate electrode 120_B. The first lower gate electrode 120_B may be disposed between the first sheet patterns NS1 adjacent to each other in the third direction D3. The first lower gate electrode 120_B may be disposed between the plurality of first sheet patterns NS1, and may be disposed between the first lower pattern BP1 and the first sheet pattern NS1 at the lowest position among the plurality of first sheet patterns NS1. The first upper gate electrode 120_U may be disposed on the first sheet pattern NS1 at the uppermost position among the plurality of first sheet patterns NS1.

In one or more embodiments of the present disclosure, the first active pattern AP1 may include the plurality of first sheet patterns NS1, and the first gate structure 120 may include a plurality of first lower gate electrodes 120_B. Here, the number of the first lower gate electrodes 120_B may be proportional to the number of the first sheet patterns NS1 included in the first active pattern AP1. The number of the first lower gate electrodes 120_B may be equal to the number of the first sheet patterns NS1. For example, as illustrated in FIG. 2, the number of the first lower gate electrodes 120_B may be three, which is the number of the first sheet patterns NS1. However, the present disclosure is not limited thereto.

The first gate structure 120 may contain at least one of a metal, a metal alloy, a conductive metal nitride, a metal silicide, a doped semiconductor material, a conductive metal oxide, and a conductive metal oxynitride. For example, the first gate structure 120 may contain at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof. However, the present disclosure is not limited thereto. The conductive metal oxide and the conductive metal oxynitride may contain the above-mentioned materials in oxidized form, but the present disclosure is not limited thereto.

The first gate insulating film 130 may be disposed between the first gate structure 120 and the plurality of first sheet patterns NS1, between the first gate structure 120 and the first lower pattern BP1, and between the first gate structure 120 and the first source/drain pattern 150. Specifically, the first gate insulating film 130 may be disposed between the first upper gate electrode 120_U and the first sheet pattern NS1 at the uppermost among the plurality of first sheet patterns NS1. The first gate insulating film 130 may be disposed between the first lower gate electrode 120_B and the first sheet pattern NS1. The first gate insulating film 130 may surround the first sheet pattern NS1. The first gate insulating film 130 may extend in the first direction D1 along the upper and lower surfaces of the first sheet pattern NS1.

The first gate insulating film 130 may contain, for example, at least one of silicon oxide, silicon oxynitride, and silicon nitride.

The first high-k insulating film 140 may be disposed on the first gate insulating film 130. The first high-k insulating film 140 may be disposed between the first gate insulating film 130 and the plurality of first sheet patterns NS1 and between the first gate insulating film 130 and the first source/drain pattern 150. The first high-k insulating film 140 may surround the first gate insulating film 130. A portion of the first high-k insulating film 140 may be disposed between a side surface of the first upper gate electrode 120_U and a side surface of a first gate spacer 165.

The first high-k insulating film 140 may contain a first high-k material having a higher dielectric constant than the first gate insulating film 130. For example, the first high-k material may include at least one of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

The first gate spacer 165 may be disposed on the side surface of the first upper gate electrode 120_U. For example, the first gate spacer 165 may extend along the side surface of the first upper gate electrode 120_U. The first gate spacer 165 may not be disposed between the first lower pattern BP1 and the first sheet pattern NS1. The first gate spacer 165 may not be disposed between the first sheet patterns NS1 adjacent to each other in the third direction D3. For example, the first gate spacer 165 may contain at least one of silicon nitride (SiN), silicon oxynitride (SiON), silicon oxide (SiO2), silicon carbonitride (SiOCN), silicon boron nitride (SiBN), silicon oxyboron nitride (SiOBN), silicon oxycarbide (SiOC), and combinations thereof. The first gate spacer 165 formed of a single film has been illustrated, which is only for convenience of description, but the present disclosure is not limited thereto.

The first gate capping pattern 170 may be disposed on the first upper gate electrode 120_U and the first gate spacer 165. A side surface of the first gate capping pattern 170 may be in contact with a first etching stop film 155. The first gate capping pattern 170 may cover an upper surface of the first upper gate electrode 120_U and an upper surface of the first gate spacer 165. The first gate capping pattern 170 may overlap the first upper gate electrode 120_U in the third direction D3. An upper surface of the first gate capping pattern 170 and an upper surface of a first interlayer insulating film 160 may be disposed on the same plane. However, the present disclosure is not limited thereto.

Although the first gate capping pattern 170 disposed on the upper surface of the first gate spacer 165 has been illustrated, the present disclosure is not limited thereto. For example, the first gate spacer 165 may protrude beyond the upper surface of the first upper gate electrode 120_U so that the first gate capping pattern 170 may be disposed between the first gate spacers 165.

The first gate capping pattern 170 may contain, for example, at least one of silicon nitride (SiN), silicon oxynitride (SiON), silicon carbon nitride (SiCN), silicon oxycarbon nitride (SiOCN), and combinations thereof. The first gate capping pattern 170 may contain a material having an etching selectivity with respect to the first interlayer insulating film 160.

The first source/drain pattern 150 may be disposed within a first source/drain trench extending in the third direction D3. The first source/drain pattern 150 may fill the first source/drain trench. A lower surface of the first source/drain trench may be defined by the first lower pattern BP1. A side surface of the first source/drain trench may be defined by sidewalls of the first lower pattern BP1, the first sheet pattern NS1, and the first high-k insulating film 140.

The first source/drain pattern 150 may be disposed on the first active pattern AP1. The first source/drain pattern 150 may be disposed on the first lower pattern BP1. The first source/drain pattern 150 may be connected to the first sheet pattern NS1. A portion of the first source/drain pattern 150 may be in contact with the first sheet pattern NS1. Another portion of the first source/drain pattern 150 may be in contact with the first gate insulating film 130. The first source/drain pattern 150 may connect the first sheet patterns NS1 spaced apart from each other in the first direction D1. The first source/drain pattern 150 may be disposed between the first sheet patterns NS1 spaced apart from each other in the first direction D1.

The first source/drain pattern 150 may be disposed on at least one side of the first gate structure 120. The first source/drain pattern 150 may be disposed between the first gate structures 120 adjacent to each other in the first direction D1. For example, the first source/drain pattern 150 may be disposed on both sides of the first lower gate electrode 120_B. Unlike the drawing, the first source/drain pattern 150 may be disposed on one side of the first gate structure 120, but may not be disposed on the other side of the first gate structure 120.

The first source/drain pattern 150 may be an epitaxial pattern formed by a selective epitaxial growth process in which the first active pattern AP1 is used as a seed. The first source/drain pattern 150 may serve as a source/drain of a transistor that uses the first sheet pattern NS1 as a channel region.

The first source/drain pattern 150 may contain a semiconductor material. The first source/drain pattern 150 may contain, for example, an elemental semiconductor material, such as silicon (Si) or germanium (Ge). In addition, for example, the first source/drain pattern 150 may contain a binary compound or a ternary compound containing at least two of carbon (C), silicon (Si), germanium (Ge), and tin (Sn), or a compound formed by doping one of those materials with a group IV element. For example, the first source/drain pattern 150 may contain silicon (Si), silicon-germanium (SiGe), germanium (Ge), silicon carbide (SiC), etc., but the present disclosure is not limited thereto.

The first source/drain pattern 150 may contain an dopant with which a semiconductor material has been doped. The dopant for doping may include at least one of boron (B), phosphorus (P), carbon (C), arsenic (As), antimony (Sb), bismuth (Bi), and oxygen (O), but the present disclosure is not limited thereto.

The first source/drain pattern 150 formed of a single film has been illustrated, which is only for convenience of description, but the present disclosure is not limited thereto. In one or more embodiments, the first source/drain pattern 150 may include multiple films containing different materials. In another embodiment, the first source/drain pattern 150 may include multiple layers containing the same material and having different concentrations of the material.

The semiconductor device according to one or more embodiments of the present disclosure may further include a lower source/drain contact. The lower source/drain contact may be disposed on the first source/drain pattern 150. In one or more embodiments, the lower source/drain contact may penetrate the first interlayer insulating film 160 and the first etching stop film 155 and be connected to the first source/drain pattern 150. In another embodiment, the lower source/drain contact may penetrate the first substrate 100 and be connected to the first source/drain pattern 150.

The first etching stop film 155 may extend along the profile of a side surface of the first gate spacer 165, the side surface of the first gate capping pattern 170, and an upper surface of the first source/drain pattern 150. The first etching stop film 155 may be disposed on an upper surface of the first field insulating film 105.

The first etching stop film 155 may contain a material having an etching selectivity with respect to the first interlayer insulating film 160. For example, the first etching stop film 155 may contain at least one of silicon nitride (SiN), silicon oxide (SiO), silicon oxynitride (SiON), silicon oxycarbonitride (SiOCN), silicon boron nitride (SiBN), silicon oxyboron nitride (SiOBN), silicon oxycarbide (SiOC), and combinations thereof.

The first interlayer insulating film 160 may be disposed on the first etching stop film 155. The first interlayer insulating film 160 may be disposed on the first source/drain pattern 150. The first interlayer insulating film 160 may be disposed on one side of the first upper gate electrode 120_U. The first interlayer insulating film 160 may be disposed between the first upper gate electrodes 120_U.

The first interlayer insulating film 160 may contain, for example, at least one of silicon oxide (SiO), silicon nitride (SiN), silicon oxynitride (SiON), and a low-k material. For example, the low-k material may include fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, and combinations thereof. However, the present disclosure is not limited thereto.

The bonding layer 190 may be disposed on the upper surface of the first gate capping pattern 170 and an upper surface of the first interlayer insulating film 160. The bonding layer 190 may cover the upper surface of the first gate capping pattern 170 and the upper surface of the first interlayer insulating film 160. For example, the bonding layer 190 may contain at least one of silicon oxide (SiO), silicon nitride (SiN), silicon oxynitride (SiON), silicon oxycarbonitride (SiOCN), silicon boron nitride (SiBN), silicon oxyboron nitride (SiOBN), silicon oxycarbide (SiOC), and combinations thereof.

Although the bonding layer 190 formed of a single film has been illustrated, the present disclosure is not limited thereto. For example, the bonding layer 190 may include multiple layers including a silicon oxide layer and a silicon nitride layer.

The second substrate 200 may be disposed on the bonding layer 190. The second substrate 200 may be bulk silicon or SOI. In another embodiment, the second substrate 200 may contain silicon germanium (SiGe), SGOI, indium antimonide, a lead tellurium compound, indium arsenide, indium phosphide, gallium arsenide, or gallium antimonide, but the present disclosure is not limited thereto.

The second active pattern AP2 may be disposed on the second substrate 200. The second active pattern AP2 may extend in the first direction D1. The second active pattern AP2 may be disposed above the first active pattern AP1. The second active pattern AP2 may overlap the first active pattern AP1 in the third direction D3.

In one or more embodiments, the first active pattern AP1 may be a region where a p-channel metal-oxide semiconductor (PMOS) is formed, and the second active pattern AP2 may be a region where an n-channel metal-oxide semiconductor (NMOS) is formed. However, the present disclosure is not limited thereto.

The second active pattern AP2 may be a multi-channel active pattern. The second active pattern AP2 may include a second lower pattern BP2 and a plurality of second sheet patterns NS2.

The second lower pattern BP2 may protrude from the second substrate 200. The second lower pattern BP2 may extend in the first direction D1. The second lower pattern BP2 may be spaced apart from the second lower pattern BP2 adjacent thereto in the second direction D2. The second lower pattern BP2 and the second lower pattern BP2 adjacent thereto may be separated by a second field trench FT2. The second field trench FT2 may be defined as an upper surface of the second substrate 200 and a side surface of the second lower pattern BP2.

The plurality of second sheet patterns NS2 may be disposed on the second lower pattern BP2. The plurality of second sheet patterns NS2 may be spaced apart from the second lower pattern BP2 in the third direction D3. The second sheet patterns NS2 may be spaced apart from each other in the third direction D3. In one or more embodiments, the second sheet pattern NS2 may have a nanosheet shape. Although three second sheet patterns NS2 have been illustrated, the present disclosure is not limited thereto.

In one or more embodiments, the second lower pattern BP2 may be formed by etching a portion of the second substrate 200, but the present disclosure is not limited thereto. For example, the second lower pattern BP2 may include an epitaxial layer grown from the second substrate 200. The second lower pattern BP2 may contain an elemental semiconductor material, such as silicon (Si) or germanium (Ge). In addition, the second lower pattern BP2 may contain a compound semiconductor. For example, the second lower pattern BP2 may contain a group IV-IV compound semiconductor or a group III-V compound semiconductor.

For example, the group IV-IV compound semiconductor may be a binary compound or ternary compound containing at least two of carbon (C), silicon (Si), germanium (Ge), and tin (Sn).

For example, the group III-V compound semiconductor may be a binary compound, a ternary compound, or a quaternary compound formed by combining at least one of aluminum (Al), gallium (Ga), and indium (In), which are group III elements, with one of phosphorus (P), arsenic (As), and antimony (Sb), which are group V elements.

In one or more embodiments, the second sheet pattern NS2 may contain one of an elemental semiconductor material, such as silicon (Si) or silicon germanium (SiGe), the group IV-IV compound semiconductor, and the group III-V compound semiconductor. The plurality of second sheet patterns NS2 may contain the same material as that in the second lower pattern BP2 or a material different from that in the second lower pattern BP2.

In another embodiment, the second sheet pattern NS2 may contain a two-dimensional material. The two-dimensional material may include a two-dimensional allotrope, a two-dimensional compound, or a transition metal dichalcogenide (TMD). The two-dimensional material may include, for example, any one of graphene, boron nitride (BN), molybdenum sulfide, molybdenum selenide, tungsten sulfide, tungsten selenide, and tantalum sulfide.

A second field insulating film 205 may be disposed on the second substrate 200. The second field insulating film 205 may fill at least a portion of the second field trench FT2. The second field insulating film 205 may be disposed between the second lower patterns BP2 adjacent to each other. The second field insulating film 205 may extend in the first direction D1. The second field insulating film 205 may be formed on the upper surface of the second substrate 200. The second field insulating film 205 may cover the side surface of the second lower pattern BP2. For example, the second field insulating film 205 may cover the side surface of the second lower pattern BP2, but may not be disposed on an upper surface of the second lower pattern BP2.

The second field insulating film 205 may contain, for example, an oxide, a nitride, an oxynitride, or combinations thereof. Although the second field insulating film 205 formed of a single film has been illustrated, which is only for convenience of description, the present disclosure is not limited thereto. For example, the second field insulating film 205 may be formed of multiple films.

The second gate structure 220 may extend in the second direction D2 on the second substrate 200. The second gate structure 220 may intersect with the second active pattern AP2. The second gate structure 220 may be disposed on the second lower pattern BP2. The second gate structure 220 may be spaced apart from the second gate structure 220 adjacent thereto in the first direction D1. The second gate structure 220 may surround the plurality of second sheet patterns NS2. The second gate structure 220 may surround four sides of the second sheet pattern NS2. For example, the second gate structure 220 may surround an upper surface, a lower surface, and both side surfaces of the second sheet pattern NS2. Here, the upper and lower surfaces of the second sheet pattern NS2 may face each other in the third direction D3, and the two side surfaces of the second sheet pattern NS2 may face each other in the second direction D2.

The second gate structure 220 may include a second upper gate electrode 220_U and a second lower gate electrode 220_B. The second lower gate electrode 220_B may be disposed between the second sheet patterns NS2 adjacent to each other in the third direction D3. The second lower gate electrode 220_B may be disposed between the plurality of second sheet patterns NS2, and may be disposed between the second lower pattern BP2 and the second sheet pattern NS2 at the lowest position among the plurality of second sheet patterns NS2. The second upper gate electrode 220_U may be disposed on the second sheet pattern NS2 at the uppermost among the plurality of second sheet patterns NS2.

In one or more embodiments, the second active pattern AP2 may include the plurality of second sheet patterns NS2, and the second gate structure 220 may include a plurality of second lower gate electrodes 220_B. Here, the number of the second lower gate electrodes 220_B may be proportional to the number of the second sheet patterns NS2 included in the second active pattern AP2. The number of the second lower gate electrodes 220_B may be equal to the number of the second sheet patterns NS2. For example, as illustrated in FIG. 2, the number of the second lower gate electrodes 220_B may be three, which is the number of the second sheet patterns NS2. However, the present disclosure is not limited thereto.

The second gate structure 220 may contain at least one of a metal, a metal alloy, a conductive metal nitride, a metal silicide, a doped semiconductor material, a conductive metal oxide, and a conductive metal oxynitride. The description of the material in the second gate structure 220 may be identical to that of the material in the first gate structure 120.

The first gate structure 120 and the second gate structure 220, both of which are formed of a single film, have been illustrated, but the present disclosure is not limited thereto. For example, each of the first gate structure 120 and the second gate structure 220 may include a work function control film that controls a work function and a filling conductive film that fills a space formed by the work function control film. The work function control film may contain, for example, at least one of titanium nitride (TiN), tantalum nitride (TaN), titanium carbide (TiC), tantalum carbide (TaC), titanium aluminum carbide (TiAlC), and combinations thereof. The filling conductive film may contain, for example, tungsten (W) or aluminum (Al).

In one or more embodiments, the work function control film of the first gate structure 120 and the work function control film of the second gate structure 220 may contain different materials. In one or more embodiments, the work function control film of the first gate structure 120 may include a P-type work function control film, and the work function control film of the second gate structure 220 may include an N-type work function control film. However, the present disclosure is not limited thereto.

The second gate insulating film 230 may be disposed between the second gate structure 220 and the plurality of second sheet patterns NS2, between the second gate structure 220 and the second lower pattern BP2, and between the second gate structure 220 and the second source/drain pattern 250. Specifically, the second gate insulating film 230 may be disposed between the second upper gate electrode 220_U and the second sheet pattern NS2 at the uppermost position among the plurality of second sheet patterns NS2. The second gate insulating film 230 may be disposed between the second lower gate electrode 220_B and the second sheet pattern NS2. The second gate insulating film 230 may surround the second sheet pattern NS2. The second gate insulating film 230 may extend in the first direction D1 along the upper and lower surfaces of the second sheet pattern NS2.

The second gate insulating film 230 may contain, for example, at least one of silicon oxide, silicon oxynitride, silicon nitride, aluminum oxide, aluminum oxynitride, molybdenum, molybdenum oxide, tungsten oxide, tantalum oxide, titanium oxide, and hexagonal boron nitride (hBN).

The second high-k insulating film 240 may be disposed on the second gate insulating film 230. The second high-k insulating film 240 may be disposed between the second gate insulating film 230 and the plurality of second sheet patterns NS2 and between the second gate insulating film 230 and the second source/drain pattern 250. The second high-k insulating film 240 may surround the second gate insulating film 230. A portion of the second high-k insulating film 240 may be disposed between a side surface of the second upper gate electrode 220_U and a side surface of a second gate spacer 265.

The second high-k insulating film 240 may contain a second high-k material having a higher dielectric constant than the second gate insulating film 230. For example, the second high-k material may include at least one of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

Hereinafter, the first high-k insulating film 140 and the second high-k insulating film 240 will be described in detail with reference to FIGS. 4 to 7.

The first high-k insulating film 140 may contain a first dopant IM1 and the first high-k material. A first portion 140_P1 of the first high-k insulating film 140 may be adjacent to the plurality of first sheet patterns NS1, and a second portion 140_P2 of the first high-k insulating film 140 may be adjacent to the first gate structure 120.

The concentration of the first dopant IM1 in the first portion 140_P1 of the first high-k insulating film 140 may be higher than the concentration of the first dopant IM1 in the second portion 140_P2 of the first high-k insulating film 140. The concentration of the first dopant IM1 may be highest at the interface between the first gate insulating film 130 and the first high-k insulating film 140. The concentration of the first dopant IM1 may decrease as a distance from the interface between the first gate insulating film 130 and the first high-k insulating film 140 increases in a direction moving toward the first gate structure 120.

The second high-k insulating film 240 may contain a second dopant IM2 and the second high-k material. A first portion 240_P1 of the second high-k insulating film 240 may be adjacent to the plurality of second sheet patterns NS2, and a second portion 240_P2 of the second high-k insulating film 240 may be adjacent to the second gate structure 220.

The concentration of the second dopant IM2 in the first portion 240_P1 of the second high-k insulating film 240 may be equal to the concentration of the second dopant IM2 in the second portion 240_P2 of the second high-k insulating film 240. Here, when the two concentrations are said to be equal to each other, it may mean that they are substantially equal to each other, including a process error range. The concentration of the second dopant IM2 may be constant in the second high-k insulating film 240. That is, the concentration of the second dopant IM2 may be constant even when getting further from the interface between the second gate insulating film 230 and the second high-k insulating film 240 toward the second gate structure 220.

In one or more embodiments, the concentration of the second dopant IM2 in the second high-k insulating film 240 may be different from the concentration shown in the drawing. The second dopant IM2 in the second high-k insulating film 240 may be distributed in a specific region and not distributed in the other regions. For example, the second dopant IM2 may be distributed in one of upper, middle, and lower portions of the second high-k insulating film 240, but may not be distributed in the other portions. Here, the upper portion of the second high-k insulating film 240 may be a region adjacent to the second gate structure 220, the lower portion of the second high-k insulating film 240 may be a region adjacent to the second gate insulating film 230, and the middle portion of the second high-k insulating film 240 may be a region between the upper portion and the lower portion. For example, the distribution of the concentration of the second dopant IM2 in the second high-k insulating film 240 may be similar to the distribution on a Gaussian graph in any one of the upper, middle, and lower portions. For another example, the concentration of the second dopant IM2 in the second high-k insulating film 240 may be constant in any one of the upper, middle, and lower portions.

The second dopant IM2 may include a material different from that in the first dopant IM1. The first dopant IM1 may include, for example, any one of gallium (Ga), and the second dopant IM2 may include any one of silicon (Si), aluminum (Al), zirconium (Zr), yttrium (Y), scandium (Sc), nitrogen (N), gadolinium (Gd), and germanium (Ge).

In one or more embodiments, the first high-k material may be identical to the second high-k material. In another embodiment, the first high-k material may be different from the second high-k material. For example, the first high-k material may include hafnium oxide, and the second high-k material may include a ternary or quaternary compound containing hafnium.

Referring back to FIGS. 1 to 7, the second gate spacer 265 may be disposed on a side surface of the second upper gate electrode 220_U. For example, the second gate spacer 265 may extend along the side surface of the second upper gate electrode 220_U. The second gate spacer 265 may not be disposed between the second lower pattern BP2 and the second sheet pattern NS2. The second gate spacer 265 may not be disposed between the second sheet patterns NS2 adjacent to each other in the third direction D3.

A second gate capping pattern 270 may be disposed on the second upper gate electrode 220_U and the second gate spacer 265. A side surface of the second gate capping pattern 270 may be in contact with a second etching stop film 255. The second gate capping pattern 270 may cover an upper surface of the second upper gate electrode 220_U and an upper surface of the second gate spacer 265. The second gate capping pattern 270 may overlap the second upper gate electrode 220_U in the third direction D3. An upper surface of the second gate capping pattern 270 and an upper surface of a second interlayer insulating film 260 may be disposed on the same plane. However, the present disclosure is not limited thereto.

Although the second gate capping pattern 270 disposed on the upper surface of the second gate spacer 265 has been illustrated, the present disclosure is not limited thereto. For example, the second gate spacer 265 may protrude beyond the upper surface of the second upper gate electrode 220_U so that the second gate capping pattern 270 may be disposed between the second gate spacers 265. The second gate capping pattern 270 may contain a material having an etching selectivity with respect to the second interlayer insulating film 260.

The description of materials in each of the second gate capping pattern 270 and the second gate spacer 265 may be identical to the description of those in each of the first gate capping pattern 170 and the first gate spacer 165.

The second source/drain pattern 250 may be disposed within a second source/drain trench extending in the third direction D3. The second source/drain pattern 250 may fill the second source/drain trench. A lower surface of the second source/drain trench may be defined by the second lower pattern BP2. A side surface of the second source/drain trench may be defined by sidewalls of the second lower pattern BP2, the second sheet pattern NS2, and the second high-k insulating film 240.

The second source/drain pattern 250 may be disposed on the second active pattern AP2. The second source/drain pattern 250 may be disposed on the second lower pattern BP2. The second source/drain pattern 250 may be connected to the second sheet pattern NS2. A portion of the second source/drain pattern 250 may be in contact with the second sheet pattern NS2. Another portion of the second source/drain pattern 250 may be in contact with the second gate insulating film 230. The second source/drain pattern 250 may connect the second sheet patterns NS2 spaced apart from each other in the first direction D1. The second source/drain pattern 250 may be disposed between the second sheet patterns NS2 spaced apart from each other in the first direction D1.

The second source/drain pattern 250 may be disposed on at least one side of the second gate structure 220. The second source/drain pattern 250 may be disposed between the second gate structures 220 adjacent to each other in the first direction D1. For example, the second source/drain pattern 250 may be disposed on both sides of the second lower gate electrode 220_B. Unlike the drawing, the second source/drain pattern 250 may be disposed on one side of the second gate structure 220, but may not be disposed on the other side of the second gate structure 220.

The second source/drain pattern 250 may be an epitaxial pattern formed by a selective epitaxial growth process in which the second active pattern AP2 is used as a seed. The second source/drain pattern 250 may serve as a source/drain of a transistor that uses the second sheet pattern NS2 as a channel region.

The second source/drain pattern 250 may contain a semiconductor material. The description of the material in the second source/drain pattern 250 may be identical to the description of that in the first source/drain pattern 150.

Although the second source/drain pattern 250 formed of a single film has been illustrated, which is only for convenience of description, the present disclosure is not limited thereto. In one or more embodiments, the second source/drain pattern 250 may include multiple films containing different materials. In another embodiment, the second source/drain pattern 250 may include multiple layers containing the same material and having different concentrations of the material.

The semiconductor device according to one or more embodiments may further include an upper source/drain contact. The upper source/drain contact may be disposed on the second source/drain pattern 250. The upper source/drain contact may penetrate the second interlayer insulating film 260 and the second etching stop film 255 to be connected to the second source/drain pattern 250.

The second etching stop film 255 may extend along the profile of a side surface of the second gate spacer 265 and an upper surface of the second source/drain pattern 250. The second etching stop film 255 may be disposed on an upper surface of the second field insulating film 205.

The second interlayer insulating film 260 may be disposed on the second etching stop film 255. The second interlayer insulating film 260 may be disposed on the second source/drain pattern 250. The second interlayer insulating film 260 may be disposed on one side of the second upper gate electrode 220_U. The second interlayer insulating film 260 may be disposed between the second upper gate electrodes 220_U.

The second etching stop film 255 may contain a material having an etching selectivity with respect to the second interlayer insulating film 260. The description of the material in the second etching stop film 255 may be identical to the description of the material in the first etching stop film 155. The description of the material in the second interlayer insulating film 260 may be identical to the description of the material in the first interlayer insulating film 160.

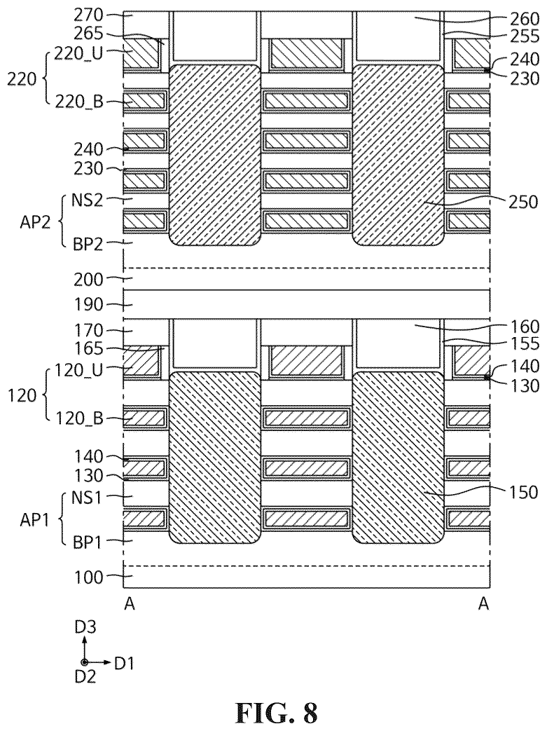

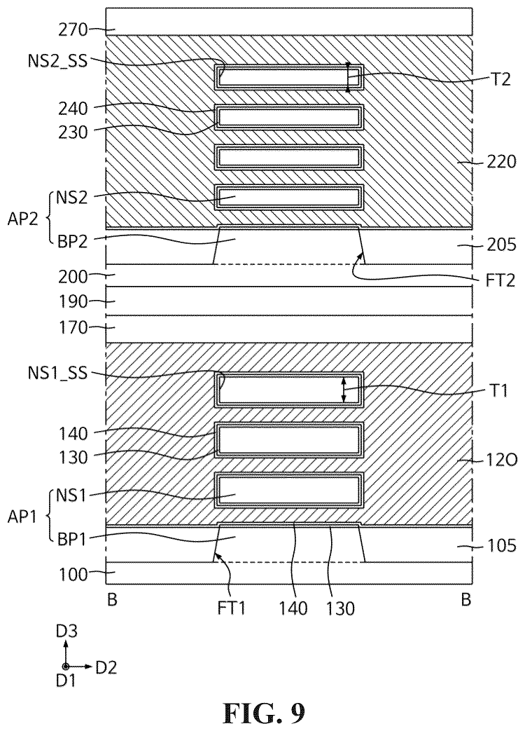

FIGS. 8 and 9 are views for illustrating a semiconductor device according to one or more embodiments of the present disclosure. For reference, FIG. 8 may correspond to a cross-sectional view taken along line A-A in FIG. 1, and FIG. 9 may correspond to a cross-sectional view taken along line B-B in FIG. 1. For convenience of description, components other than those described with reference to FIGS. 1 to 7 will be mainly described.

Referring to FIGS. 8 and 9, the second active pattern AP2 of the semiconductor device according to one or more embodiments may include the second lower pattern BP2 and the plurality of second sheet patterns NS2.

The plurality of second sheet patterns NS2 may be disposed on the second lower pattern BP2. The plurality of second sheet patterns NS2 may be spaced apart from the second lower pattern BP2 in the third direction D3. The second sheet patterns NS2 may be spaced apart from each other in the third direction D3. In one or more embodiments, the second sheet pattern NS2 may have a nanosheet shape. The number of the second sheet patterns NS2 may be four.

In one or more embodiments, the number of the second sheet patterns NS2 may be different from the number of the first sheet patterns NS1. For example, the number of the second sheet patterns NS2 may be higher than the number of the first sheet patterns NS1. However, the present disclosure is not limited thereto. The number of the second sheet patterns NS2 may be lower than or equal to the number of the first sheet patterns NS1.

The first sheet pattern NS1 may have a first thickness T1 in the third direction D3. The second sheet pattern NS2 may have a second thickness T2 in the third direction D3. The second thickness T2 may be smaller than the first thickness T1. That is, the second sheet pattern NS2 may be thinner than the first sheet pattern NS1. Because the second sheet pattern NS2 is thinner than the first sheet pattern NS1, the degree of integration of a semiconductor device including a transistor using the second sheet pattern NS2 as a channel may be improved. In addition, because the second sheet pattern NS2 is thinner, it may be possible to form a greater number of the second sheet patterns NS2 when forming a transistor of the same height. As a result, the electrical properties of the semiconductor device may be enhanced.

The second sheet pattern NS2 may contain a two-dimensional material. The two-dimensional material may include a two-dimensional allotrope, a two-dimensional compound, or a transition metal dichalcogenide (TMD). The two-dimensional material may include, for example, any one of graphene, boron nitride (BN), molybdenum sulfide, molybdenum selenide, tungsten sulfide, tungsten selenide, and tantalum sulfide.

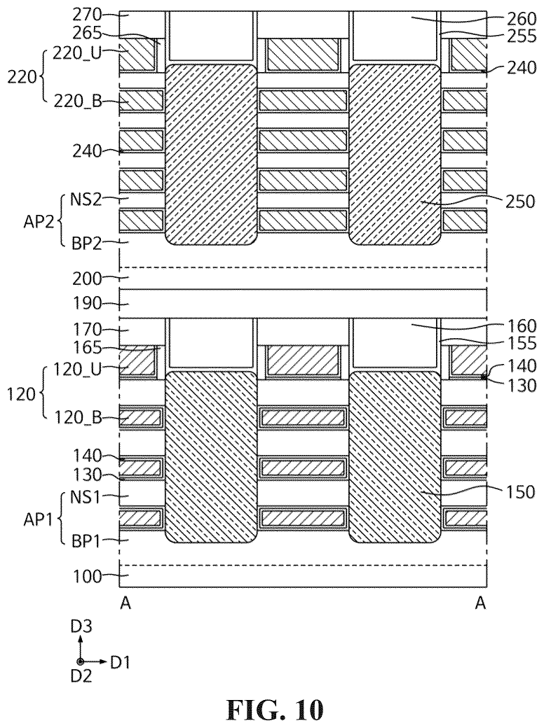

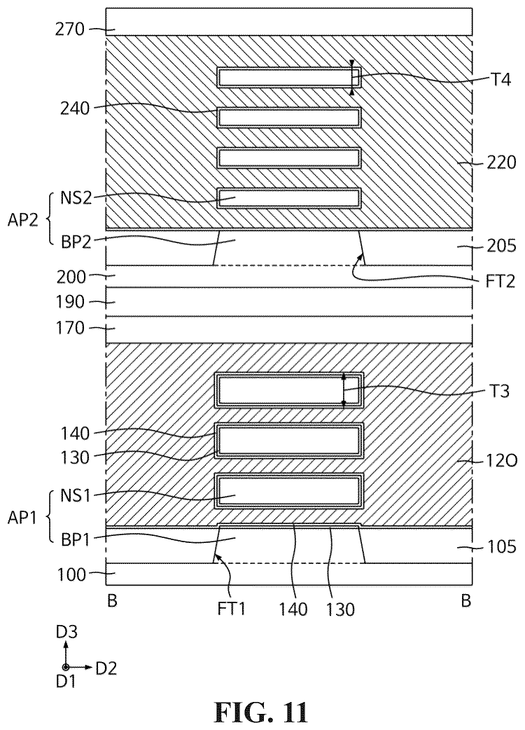

FIGS. 10 and 11 are views for illustrating a semiconductor device according to one or more embodiments of the present disclosure. For reference, FIG. 10 may correspond to a cross-sectional view taken along line A-A in FIG. 1, and FIG. 11 may correspond to a cross-sectional view taken along line B-B in FIG. 1. For convenience of description, components other than those described with reference to FIGS. 1 to 7 will be mainly described.

Referring to FIGS. 10 and 11, the second active pattern AP2 of the semiconductor device according to one or more embodiments may include the second lower pattern BP2 and the plurality of second sheet patterns NS2.

The plurality of second sheet patterns NS2 may be disposed on the second lower pattern BP2. The plurality of second sheet patterns NS2 may be spaced apart from the second lower pattern BP2 in the third direction D3. The second sheet patterns NS2 may be spaced apart from each other in the third direction D3. In one or more embodiments, the second sheet pattern NS2 may have a nanosheet shape. The number of the second sheet patterns NS2 may be four.

In one or more embodiments, the number of the second sheet patterns NS2 may be different from the number of the first sheet patterns NS1. For example, the number of the second sheet patterns NS2 may be higher than the number of the first sheet patterns NS1. The number of the second sheet patterns NS2 may be lower than or equal to the number of the first sheet patterns NS1.

The second sheet pattern NS2 may contain a two-dimensional material. The two-dimensional material may include a two-dimensional allotrope, a two-dimensional compound, or a transition metal dichalcogenide (TMD). The two-dimensional material may include, for example, any one of graphene, boron nitride (BN), molybdenum sulfide, molybdenum selenide, tungsten sulfide, tungsten selenide, and tantalum sulfide.

The second high-k insulating film 240 may be disposed on the second sheet pattern NS2. The second high-k insulating film 240 may be in contact with the second sheet pattern NS2. In other words, there may not be another component disposed between the second high-k insulating film 240 and the second sheet pattern NS2.

In one or more embodiments, the first high-k insulating film 140 may have a third thickness T3. The third thickness T3 of the first high-k insulating film 140 may be equal to the length of the first high-k insulating film 140 disposed on a side surface NS1_SS of the first sheet pattern NS1. The second high-k insulating film 240 may have a fourth thickness T4. The fourth thickness T4 of the second high-k insulating film 240 may be equal to the length of the second high-k insulating film 240 disposed on a side surface NS2_SS of the second sheet pattern NS2. The fourth thickness T4 may be smaller than the third thickness T3.

Because the second gate insulating film is not disposed on the second sheet pattern NS2 of the semiconductor device in FIGS. 10 and 11, the thickness of the second high-k insulating film 240 thereof, e.g., the fourth thickness T4, may be reduced. As a result, the degree of integration of the semiconductor device may be improved.

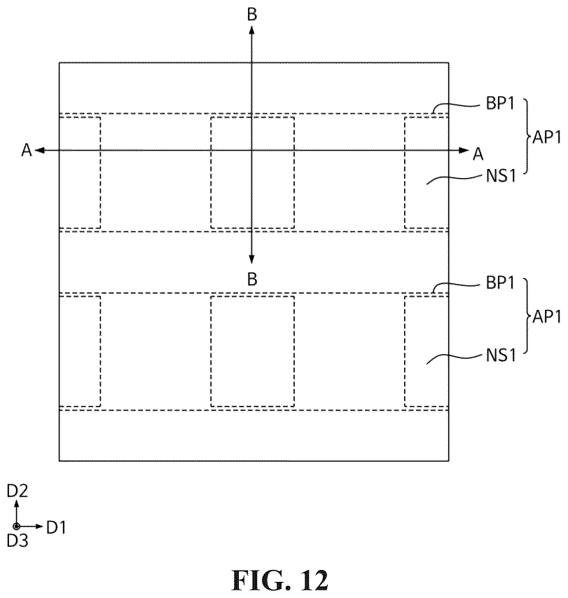

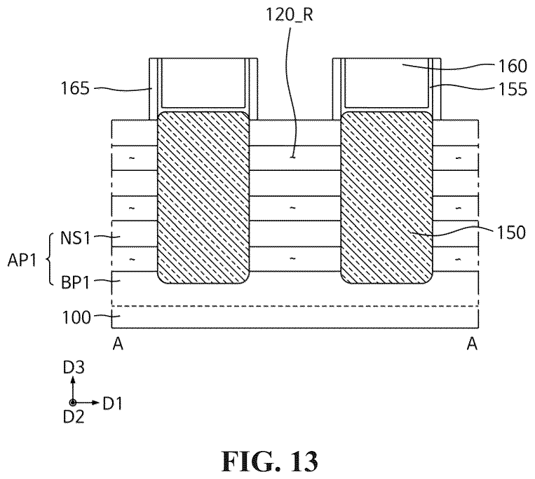

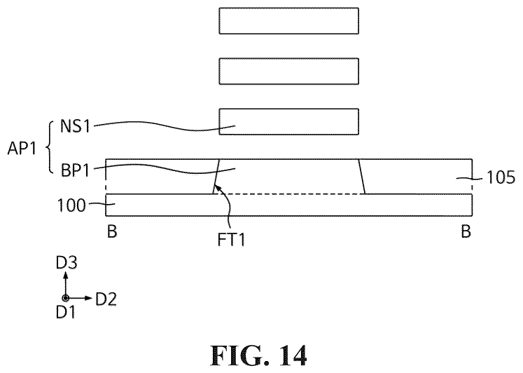

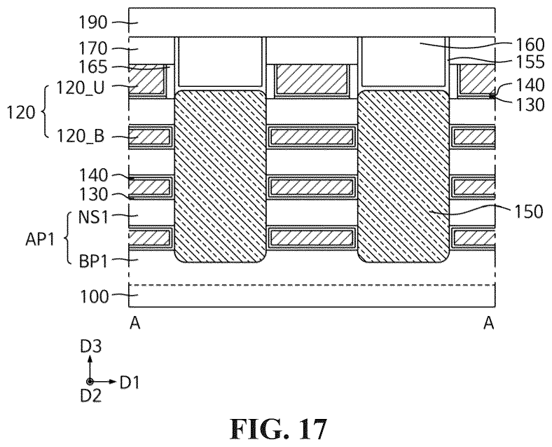

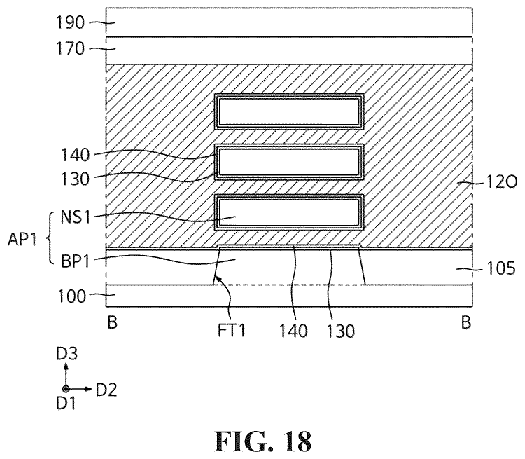

FIGS. 12 to 21 illustrate intermediate operations for a method of manufacturing a semiconductor device according to one or more embodiments of the present disclosure. For reference, FIG. 12 is a plan view of the semiconductor device according to one or more embodiments of the present disclosure. FIGS. 13 and 17 are cross-sectional views taken along line A-A in FIG. 12, and FIGS. 14, 15, 16, 18, 19, 20, and 21 are cross-sectional views taken along line B-B in FIG. 12.

Referring to FIGS. 12 to 14, on the first substrate 100, the first active pattern AP1, the first field insulating film 105, the first source/drain pattern 150, the first etching stop film 155, the first interlayer insulating film 160, and the first gate spacer 165 may be formed.

The first active pattern AP1 may include the first lower pattern BP1 and the plurality of first sheet patterns NS1. The plurality of first sheet patterns NS1 may be spaced apart from each other in the third direction D3. A gate recess 120_R may be formed between the first sheet pattern NS1 at the lowest among the plurality of first sheet patterns NS1 and the first lower pattern BP1. In addition, the gate recess 120_R may be formed between the first sheet patterns NS1 spaced apart from each other.

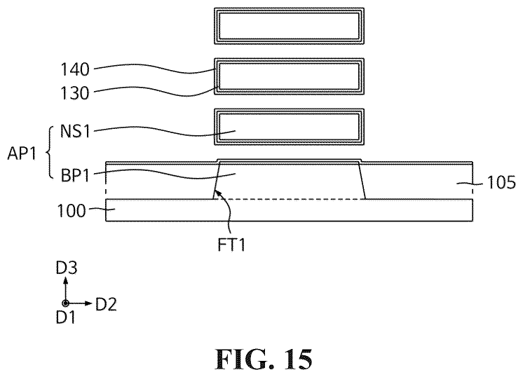

Referring to FIG. 15, the first gate insulating film 130 and the first high-k insulating film 140 may be sequentially formed on the first sheet pattern NS1. The first gate insulating film 130 may surround the first sheet pattern NS1. The first gate insulating film 130 may be in contact with the first sheet pattern NS1.

The first high-k insulating film 140 may be formed on the first gate insulating film 130. The first high-k insulating film 140 may surround the first gate insulating film 130. The first high-k insulating film 140 may include the first high-k material. The first high-k material may be as described with reference to FIGS. 1 to 7.

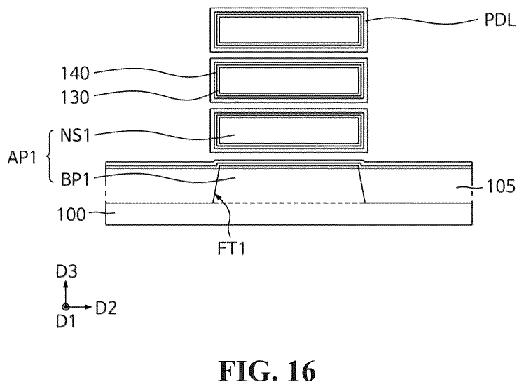

Referring to FIG. 16, a dipole film PDL may be formed on the first high-k insulating film 140. The dipole film PDL may be formed along the profile of the first high-k insulating film 140. The dipole film PDL may contain the first dopant.

Next, a first high-temperature process may be performed on the dipole film PDL. For example, the first high-temperature process may be carried out at approximately 830° C. The first high-temperature process may allow the first dopant in the dipole film PDL to diffuse into the first high-k insulating film 140. The first dopant may diffuse from the dipole film PDL into the first high-k insulating film 140 and may diffuse to the interface between the first high-k insulating film 140 and the first gate insulating film 130. Accordingly, the distribution of the first dopant in the first high-k insulating film 140 may be similar to the distribution in FIG. 5.

Referring to FIGS. 16 to 18, the dipole film PDL may be removed, and the first gate structure 120 may be formed.

According to one or more embodiments, the dipole film PDL may be eliminated, and, prior to the formation of the first gate structure 120, polysilicon (poly Si) may be deposited and then removed after a second high-temperature process has been performed. Thereafter, the first gate structure 120 may be formed. For example, the second high-temperature process may be carried out at approximately 930° C.

Next, the first gate capping pattern 170 and the bonding layer 190 may be sequentially stacked on the first gate structure 120.

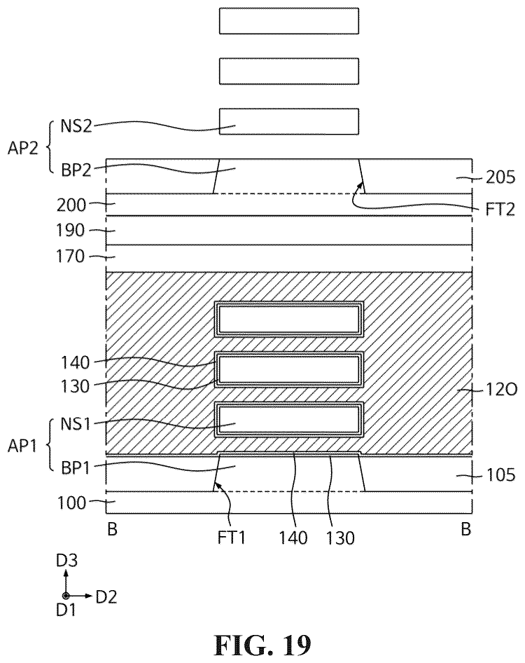

Referring to FIG. 19, on the bonding layer 190, the second substrate 200, the second active pattern AP2, and the second field insulating film 205 may be formed.

Specifically, the second substrate 200 may be formed on the bonding layer 190. Then, on the second substrate 200, the second active pattern AP2 including the plurality of second sheet patterns NS2 and the second lower pattern BP2 and the second field insulating film 205 may be formed.

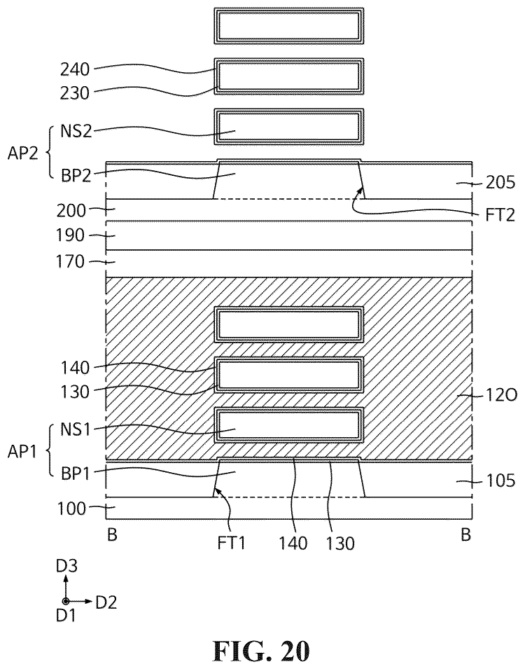

Referring to FIG. 20, the second gate insulating film 230 and the second high-k insulating film 240 may be sequentially formed on the second sheet pattern NS2. The second gate insulating film 230 may surround the second sheet pattern NS2. The second gate insulating film 230 may be in contact with the second sheet pattern NS2.

The second high-k insulating film 240 may be formed on the second gate insulating film 230. The second high-k insulating film 240 may surround the second gate insulating film 230. The second high-k insulating film 240 may contain the second high-k material. The second high-k material may be as described with reference to FIGS. 1 to 7.

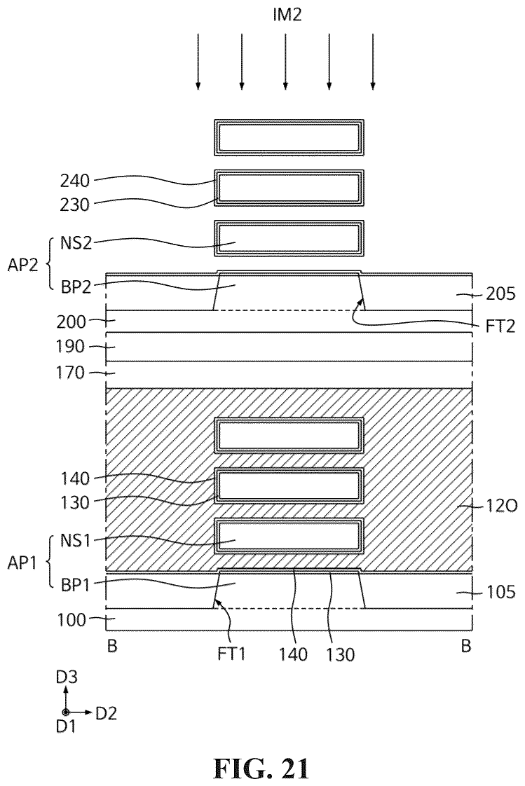

Referring to FIG. 21, a doping process and a curing process may be performed on the second high-k insulating film 240. Through the doping process, the second dopant IM2 may be doped into the second high-k insulating film 240. Next, the curing process may be carried out on the second high-k insulating film 240. The curing process may be carried out at a temperature of approximately 500° C. or less. As a result, the distribution of the second dopant IM2 in the second high-k insulating film 240 may be similar to the distribution in FIG. 7.

Some components of semiconductor devices may be vulnerable to a high temperature. For example, components of the PMOS are vulnerable to a high temperature, and their device properties may deteriorate when they are exposed to a high temperature. For the semiconductor device according to one or more embodiments of the present disclosure, a low-temperature process rather than a high-temperature process may be performed while an upper transistor is formed after a lower transistor. For example, a doping process and a curing process may be carried out while the second high-k insulating film 240 is formed on the second gate insulating film 230, so that the manufacturing process may be performed at a relatively low temperature. As a result, it may be possible to prevent the deterioration of the properties of elements of the lower transistor and improve the reliability of the semiconductor device.

Next, referring to FIG. 3, the second gate structure 220 may be formed on the second high-k insulating film 240, and the second gate capping pattern 270 may be formed on the second gate structure 220.

FIGS. 19 to 21 show that, on the bonding layer 190, the second substrate 200, the second active pattern AP2, the field insulating film 205, the second high-k insulating film 240, etc. may be formed, but the present disclosure is not limited thereto.

For example, the second substrate 200, the second active pattern AP2, and the field insulating film 205 may be formed on a separate wafer. Next, the second gate insulating film 230, the second high-k insulating film 240, the second gate structure 220, etc. may be formed on the second substrate 200 to form an upper transistor. Then, the upper transistor may be coupled to the bonding layer 190. For example, the second substrate 200 of the upper transistor may be coupled to the bonding layer 190 to form the semiconductor device in FIG. 3.

Although one or more embodiments of the present disclosure have been described with reference to the accompanying drawings, those of ordinary skill in the art to which the present disclosure pertains will understand that the present disclosure may be implemented in other specific forms without changing its technical idea or essential features. Therefore, it should be understood that the embodiments described above are illustrative and non-limiting in all respects.

What is claimed is:

1. A semiconductor device comprising:
a first substrate;
a first active pattern extending in a first direction on the first substrate, the first active pattern comprising a first lower pattern and a plurality of first sheet patterns spaced apart from each other on the first lower pattern;
a first gate structure extending in a second direction intersecting with the first direction, wherein the first gate structure surrounds the plurality of first sheet patterns;
a first high-k insulating film between the first gate structure and the plurality of first sheet patterns;
a first gate insulating film between the plurality of first sheet patterns and the first high-k insulating film;
a plurality of second sheet patterns above the plurality of first sheet patterns, wherein the plurality of second sheet patterns are spaced apart from each other;
a second gate structure extending in the second direction, wherein the second gate structure surrounds the plurality of second sheet patterns; and
a second high-k insulating film between the second gate structure and the plurality of second sheet patterns,
wherein the first high-k insulating film comprises a first dopant,
wherein the second high-k insulating film comprises a second dopant different from the first dopant, and
wherein the second dopant comprises at least one of silicon, aluminum, zirconium, yttrium, scandium, nitrogen, gadolinium, or germanium.

2. The semiconductor device of claim 1,
wherein the first high-k insulating film comprises a first portion adjacent to the plurality of first sheet patterns and a second portion adjacent to the first gate structure,
wherein the second high-k insulating film comprises a first portion adjacent to the plurality of second sheet patterns and a second portion adjacent to the second gate structure,
wherein a concentration of the first dopant in the first portion of the first high-k insulating film is higher than a concentration of the first dopant in the second portion of the first high-k insulating film, and
wherein a concentration of the second dopant in the first portion of the second high-k insulating film is equal to a concentration of the second dopant in the second portion of the second high-k insulating film.

3. The semiconductor device of claim 1,
wherein the first high-k insulating film further comprises a first high-k material, and
wherein the second high-k insulating film further comprises a second high-k material different from the first high-k material.

4. The semiconductor device of claim 1, further comprising a second gate insulating film between the plurality of second sheet patterns and the second high-k insulating film.

5. The semiconductor device of claim 1, wherein the plurality of second sheet patterns comprise a two-dimensional material.

6. The semiconductor device of claim 5,
wherein a thickness of one of the plurality of second sheet patterns in a third direction is less than a thickness of one of the plurality of first sheet patterns in the third direction, and
wherein the third direction intersects with the first direction and the second direction.

7. The semiconductor device of claim 5, wherein a number of the plurality of second sheet patterns is higher than a number of the plurality of first sheet patterns.

8. The semiconductor device of claim 5, wherein the second high-k insulating film is in contact with the plurality of second sheet patterns.

9. The semiconductor device of claim 5, further comprising a second gate insulating film between the plurality of second sheet patterns and the second high-k insulating film,
wherein the second gate insulating film comprises a material different from the first gate insulating film.

10. The semiconductor device of claim 1, further comprising:
a gate capping pattern on an upper surface of the first gate structure; and
a bonding layer between the gate capping pattern and the plurality of second sheet patterns.

11. The semiconductor device of claim 1, further comprising:
a first source/drain pattern on at least one side of the plurality of first sheet patterns; and
a second source/drain pattern on at least one side of the plurality of second sheet patterns,
wherein the first source/drain pattern comprises a P-type dopant, and the second source/drain pattern comprises an N-type dopant.

12. A semiconductor device comprising:
a first substrate;
a first active pattern extending in a first direction on the first substrate, the first active pattern comprising a plurality of first sheet patterns spaced apart from each other;
a first gate structure extending in a second direction intersecting with the first direction, wherein the first gate structure surrounds the plurality of first sheet patterns;
a first high-k insulating film between the first gate structure and the plurality of first sheet patterns, the first high-k insulating film comprising a first dopant;
a first gate insulating film between the plurality of first sheet patterns and the first high-k insulating film;
a second active pattern extending in the first direction and spaced apart from the first active pattern in a third direction, wherein the third direction intersects with the first and the second directions, and wherein the second active pattern comprises a plurality of second sheet patterns spaced apart from each other in the third direction;
a second gate structure extending in the second direction, wherein the second gate structure surrounds the plurality of second sheet patterns; and
a second high-k insulating film between the second gate structure and the plurality of second sheet patterns, the second high-k insulating film comprising a second dopant different from the first dopant,
wherein a concentration of the first dopant decreases as a distance from an interface between the first gate insulating film and the first high-k insulating film increases in the third direction, and
wherein a concentration of the second dopant is constant in the third direction.

13. The semiconductor device of claim 12, wherein the second dopant comprises at least one of silicon, aluminum, zirconium, yttrium, scandium, nitrogen, gadolinium, or germanium.

14. The semiconductor device of claim 12, further comprising:
a gate capping pattern on an upper surface of the first gate structure; and
a bonding layer between the gate capping pattern and the second active pattern.

15. The semiconductor device of claim 12,
wherein the first high-k insulating film further comprises a first high-k material, and
wherein the second high-k insulating film further comprises a second high-k material different from the first high-k material.

16. The semiconductor device of claim 15,
wherein the first high-k material comprises hafnium oxide, and
wherein the second high-k material comprises either a ternary compound containing hafnium or a quaternary compound containing hafnium.

17. The semiconductor device of claim 12, wherein the plurality of second sheet patterns comprises a material different from the plurality of first sheet patterns.

18. The semiconductor device of claim 17, wherein a number of the plurality of second sheet patterns is different from a number of the plurality of first sheet patterns.

19. The semiconductor device of claim 17, wherein a length of the first high-k insulating film on a side surface of the plurality of first sheet patterns in the third direction is longer than a length of the second high-k insulating film on a side surface of the plurality of second sheet patterns in the third direction.

20. A semiconductor device comprising:
a first substrate;
a first active pattern extending in a first direction on the first substrate, the first active pattern comprising a first lower pattern and a plurality of first sheet patterns spaced apart from each other on the first lower pattern;
a first gate structure extending in a second direction intersecting with the first direction, wherein the first gate structure surrounds the plurality of first sheet patterns;
a first high-k insulating film between the first gate structure and the plurality of first sheet patterns;
a first gate insulating film between the plurality of first sheet patterns and the first high-k insulating film;
a gate capping pattern on an upper surface of the first gate structure;
a bonding layer on the gate capping pattern;
a second substrate on the bonding layer;
a second active pattern extending in the first direction on the second substrate, the second active pattern comprising a second lower pattern and a plurality of second sheet patterns spaced apart from each other on the second lower pattern;
a second gate structure extending in the second direction, wherein the second gate structure surrounds the plurality of second sheet patterns;
a second high-k insulating film between the second gate structure and the plurality of second sheet patterns; and
a second gate insulating film between the plurality of second sheet patterns and the second high-k insulating film,
wherein the first high-k insulating film comprises a first high-k material and a first dopant,
wherein the second high-k insulating film comprises a second high-k material different from the first high-k material and a second dopant different from the first dopant,
wherein a concentration of the first dopant decreases as a distance from an interface between the first gate insulating film and the first high-k insulating film increases in a third direction,
wherein the third direction is perpendicular to an upper surface of the first substrate, and
wherein a concentration of the second dopant is constant in the third direction.
